(19) United States
(12) Patent Application Publication
(10) Pub. No.: US 2025/0318107 A1
(43) Pub. Date: Oct. 9, 2025

(54) SEMICONDUCTOR DEVICE AND METHOD OF FORMING THE SAME

(71) Applicant: NANYA TECHNOLOGY CORPORATION, New Taipei city (TW)

(72) Inventor: Ying-Cheng CHUANG, New Taipei City (TW)

(21) Appl. No.: 18/626,389

(22) Filed: Apr. 4, 2024

(51) Int. Cl. H10B 12/00

(52) U.S. Cl. CPC H10B 12/34; H10B 12/053

(57) ABSTRACT

A semiconductor device includes a substrate, an active region in the substrate, and a gate structure in the active region. The gate structure includes a bottom conductive layer, a top conductive layer on the bottom conductive layer, and a cap layer on the top conductive layer. A width of the top conductive layer is less than a width of the bottom conductive layer, a bottom of the top conductive layer is embedded in the bottom conductive layer, and a work function of the top conductive layer is identical to a work function of the bottom conductive layer. A method of forming the semiconductor device is also disclosed.

### BACKGROUND

### Field of Invention

The present disclosure relates to a semiconductor device and a method of forming the same.

### Description of Related Art

In recent decades, demand to storage capability has increased as electronic products continue to improve. In order to increase storage capability of a memory device (e.g., a DRAM device), more memory cells are integrated in the memory device. As the integration level increases, fabrication process of the memory device become much more complicated, and process window become rather narrow.

### SUMMARY

An aspect of the disclosure provides a semiconductor device including a substrate, an active region in the substrate, and a gate structure in the active region. The gate structure includes a bottom conductive layer, a top conductive layer on the bottom conductive layer, and a cap layer on the top conductive layer. A width of the top conductive layer is less than a width of the bottom conductive layer, a bottom of the top conductive layer is embedded in the bottom conductive layer, and a work function of the top conductive layer is identical to a work function of the bottom conductive layer.

In some embodiments, the bottom conductive layer includes a bottom portion entirely below the top conductive layer and a sidewall portion encircling the bottom of the top conductive layer.

In some embodiments, a material of the bottom conductive layer and the top conductive layer includes titanium nitride.

In some embodiments, a material of the cap layer comprises silicon nitride.

In some embodiments, an interface is present between the bottom conductive layer and the top conductive layer.

In some embodiments, the semiconductor device further includes a first spacer surrounding the cap layer and a third spacer surrounding the bottom conductive layer. A thickness of the first spacer is thicker than a thickness of the third spacer.

In some embodiments, the first spacer includes a nitride layer in contact with the cap layer and a first portion of an oxide material between the nitride layer and the active region.

In some embodiments, the semiconductor device further includes a second spacer surrounding the top conductive layer. A thickness of the second spacer is thicker than a thickness of the third spacer.

In some embodiments, the second spacer includes a second portion of the oxide material, and a thickness of the second portion of the oxide material is thicker than a thickness of the first portion of the oxide material.

In some embodiments, a sidewall of the nitride layer is aligned with a sidewall of the second portion of the oxide material.

In some embodiments, the semiconductor device further includes an isolation region in the substrate and a dummy gate structure in the isolation region. The dummy gate structure extends deeper than the gate structure in the substrate.

Another aspect of the disclosure provides a method of forming a semiconductor device. The method includes forming an active region in a substrate; forming a trench in the active region; depositing a lining layer in the trench; depositing a conductive material to fill the trench; etching back the conductive material and the lining layer to form a bottom conductive layer in the trench; depositing an oxide material on the bottom conductive layer; etching the oxide material to define an upper trench above the bottom conductive layer; deepening the upper trench such that a portion of the bottom conductive layer is removed; and forming a top conductive layer in the upper trench, after deepening the upper trench. A width of the top conductive layer is less than a width of the bottom conductive layer, a bottom of the top conductive layer is embedded in the bottom conductive layer, and a work function of the top conductive layer is identical to a work function of the bottom conductive layer.

In some embodiments, the top conductive layer is directly in contact with the bottom conductive layer, and an interface is present between the top conductive layer and the bottom conductive layer.

In some embodiments, etching the oxide material includes forming a first portion of the oxide material on a sidewall of the upper trench and a second portion of the oxide material on a bottom of the upper trench, and a thickness of the second portion is thicker than a thickness of the first portion.

In some embodiments, the method further includes depositing a nitride layer on the first portion and the second portion of the oxide material.

In some embodiments, deepening the upper trench includes removing a portion of the nitride layer, a portion of the second portion of the oxide material, and the portion of the bottom conductive layer.

In some embodiments, sidewalls of the nitride layer, the second portion of the oxide material, and the bottom conductive layers exposed by the upper trench are aligned after deepening the upper trench.

In some embodiments, forming a top conductive layer includes depositing additional conductive material to fill the upper trench; and etching back the additional conductive material to remove a portion of the additional conductive material between the nitride layer.

In some embodiments, the method further includes depositing a cap material to fill the upper trench and above the active region; and removing a portion of the cap material to form a cap layer on the top conductive layer.

In some embodiments, a width of the cap layer is equal to the width of the top conductive layer.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a schematic layout of a semiconductor device according to some embodiments of the disclosure; and

FIGS. 2-13 are cross-sectional views of different steps of a method of forming a semiconductor device, taken along line A-A in FIG. 1, according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

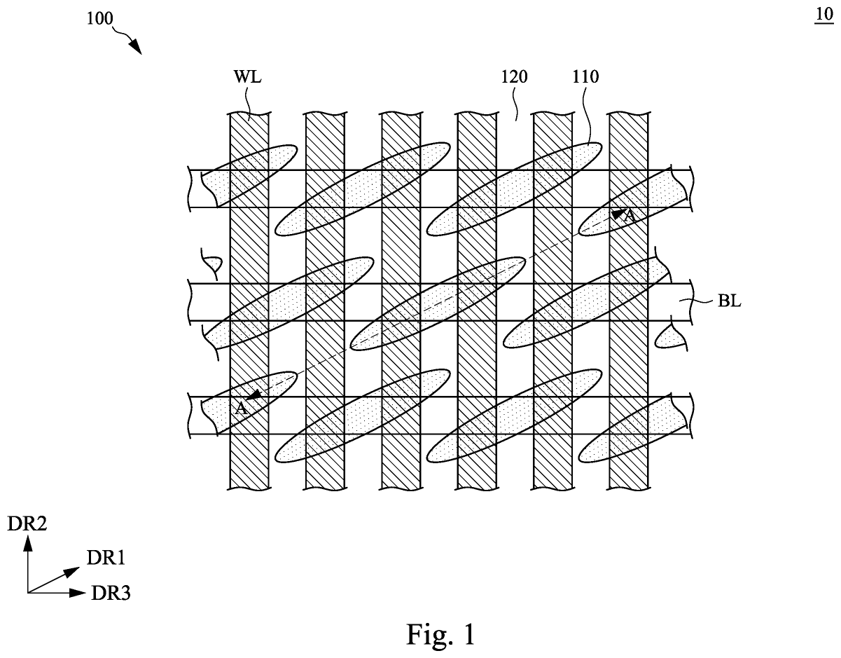

FIG. 1 is a schematic layout of a semiconductor device according to some embodiments of the disclosure. A dynamic random access memory (DRAM) array 10 is shown as an example of the semiconductor device 100 according to some embodiments of the disclosure. The semiconductor device 100 includes a plurality of active regions 110 that are defined by an isolation region 120 formed in a substrate. The active regions 110 may extend in a first direction DR1, a plurality of word lines WLs extend in a second direction DR2 which forms an angle with the first direction DR1, and a plurality of bit lines BLs extend in a third direction DR3 which forms an angle with the first direction DR1. In some embodiments, the shape of the active regions 110 can be an ellipse. The angle between the first direction DR1 and the second direction DR2 and the angle between the first direction DR1 and the third direction DR3 may be, but are not limited to, 45 and 45 degrees, 30 and 60 degrees, or 60 and 30 degrees, respectively. In some embodiments, the word lines WLs are formed perpendicular to the bit lines BLs. That is, the angle between the second direction DR2 and the third direction DR3 may be 90 degrees.

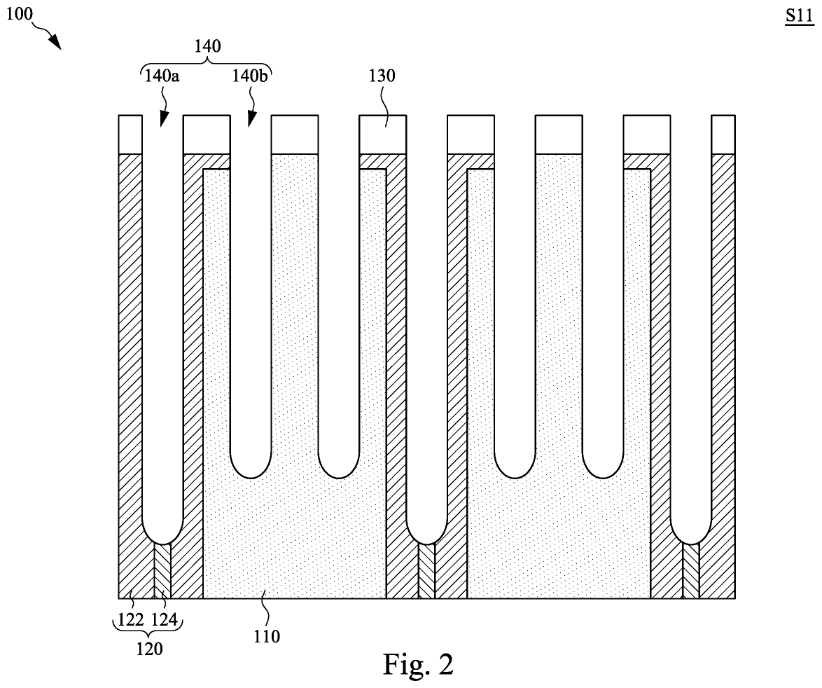

Reference is made to FIGS. 2-13, which are cross-sectional views of different steps of a method of forming a semiconductor device, taken along line A-A in FIG. 1, according to some embodiments of the disclosure. As shown in FIG. 2, the method begins at step S11. The semiconductor device 100 includes the active regions 110 defined by the isolation region 120. In some embodiments, the active regions 110 and the isolation region 120 are formed in the substrate, in which the substrate may be, for example, a silicon (Si) substrate. Alternatively, the substrate can be a Si substrate and is doped with other semiconductor materials. In some other embodiments, the substrate may include a layered semiconductor such as silicon/silicon germanium, silicon-on-insulator, or silicon germanium-on-insulator. In some embodiments, the active regions 110 may be doped with an N-type dopant such as phosphorus (P), arsenic (As), or antimony (Sb). In some other embodiments, the active regions 110 may be doped with a P-type dopant such as boron (B) or indium (In). In some embodiments, the substrate may be or include an unimplanted area. In some embodiments, the active regions 110 may have a higher doping concentration than the substrate.

The isolation region 120 is formed surrounding the active regions 110 to separate the active regions 110 from other. In some embodiments, the isolation region 120 is a multi-layer structure including an oxide layer 122 directly in contact with the active regions 110 and a nitride layer 124 sandwiched by the oxide layer 122. The multi-layer structure ensures a seamless isolation region 120 and provides better electrical isolation between the active regions 110.

A pattered hard mask layer 130 having a plurality of openings is formed on the substrate, and an etching process is performed through the openings to form plurality of trenches 140 in the active regions 110 and in the isolation region 120. In some embodiments, the trenches 140 are formed by performing a wet etching process or a dry etching process. Due to the etching selectivity of materials of the active regions 110 and the isolation region 120, the depth of the trenches 140 such as trenches 140a in the isolation region 120 is deeper than the trenches 140 such as trenches 140b in the active regions 110, and portions of the nitride layer 124 of the isolation region 120 is revealed from the trenches 140a.

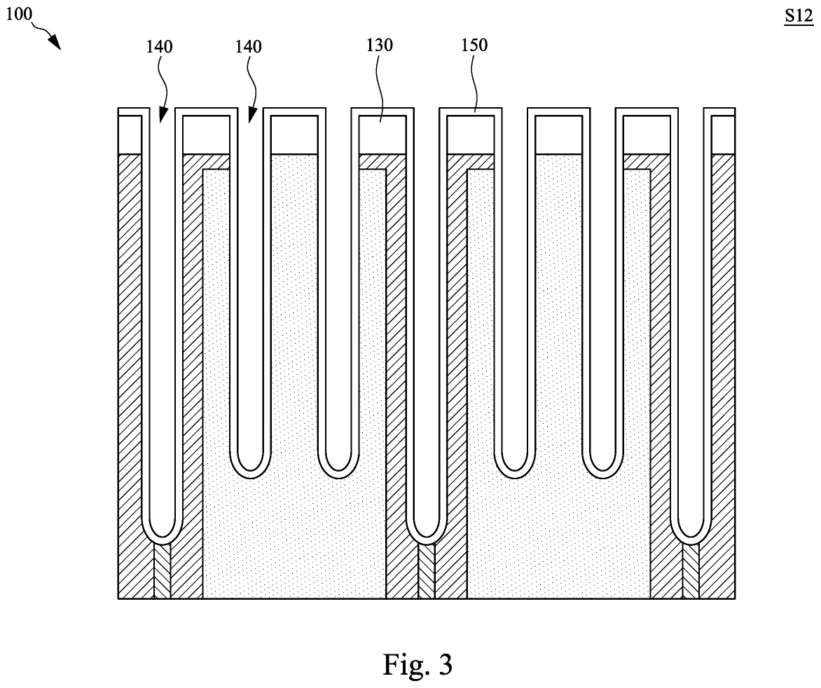

Reference is made to FIG. 3. As shown in step S12, a lining layer 150 is formed on sidewalls of the trenches 140 and on the hard mask layer 130. In some embodiments, the lining layer 150 is an oxide layer and is formed by an atomic layer deposition process such that the lining layer 150 is conformally formed on sidewalls of the trenches 140 and on the hard mask layer 130.

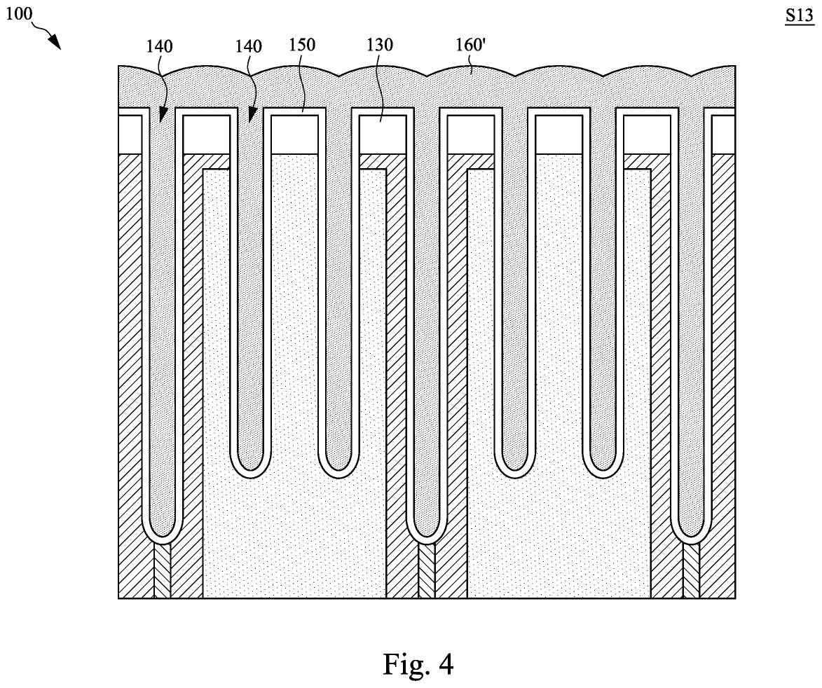

Reference is made to FIG. 4. As shown in step S13, a conductive material 160′ is deposited and fills the trenches 140. In some embodiments, the conductive material 160′ not only fills the trenches 140 but also covers the hard mask layer 130. In some embodiments, the conductive material 160′ can be titanium nitride or tungsten.

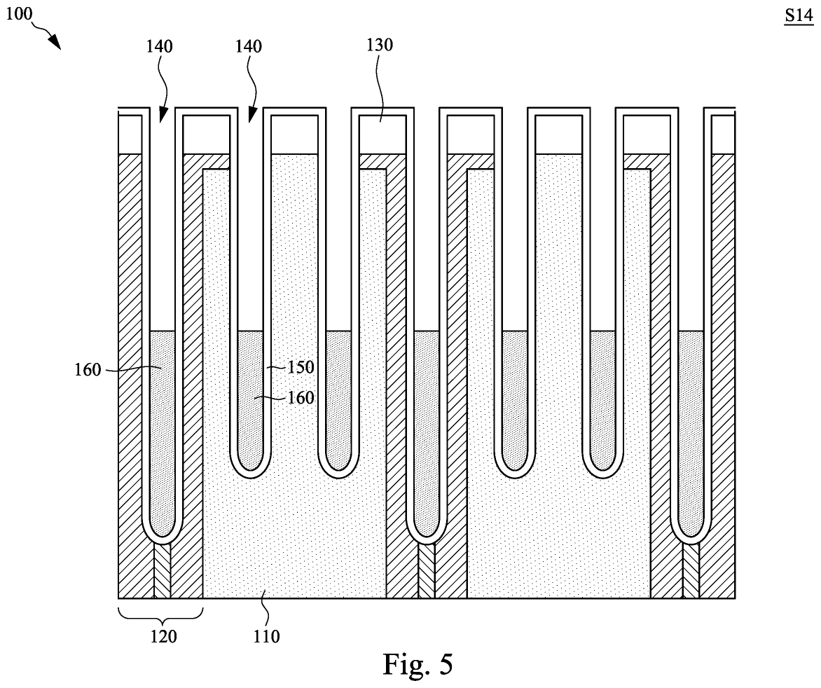

Reference is made to FIG. 5. As shown in step S14, an etch back process is performed to remove portions of the conductive material 160′ (as shown in FIG. 4) in the trenches 140 and the conductive material 160′ over the hard mask layer 130. Portions of the conductive material 160′ are remained in the bottom of the trenches 140, and the remaining portions of the conductive material 160′ can be regarded as bottom conductive layers 160 in the trenches 140. In some embodiments, the etch back process is a selective etching process which has a greater etching to the conductive material 160′ than the lining layer 150, thus the lining layer 150 is remained on the sidewalls of the trenches 140 after the etch back process is performed.

A cleaning process is performed after etch back process to remove residues of the conductive material 160′. The cleaning process can be a wet cleaning process, including using dilute HF as an etchant. The portions of the lining layer 150 at the bottom of the trenches 140 are sandwiches between the bottom conductive layers 160 and the active regions 110 or between the bottom conductive layers 160 and the isolation region 120.

In some embodiments, the lining layer 150 at top sections of the trenches 140 is not completely removed after the cleaning process is performed. Therefore, the sidewalls of the active regions 110 can be protected by the remaining lining layer 150, and thus the loss of the active regions 110 can be prevented. In some other embodiments, the lining layer 150 at top sections of the trenches 140 is completely removed after the cleaning process is performed, and the sidewalls of the active regions 110 are exposed.

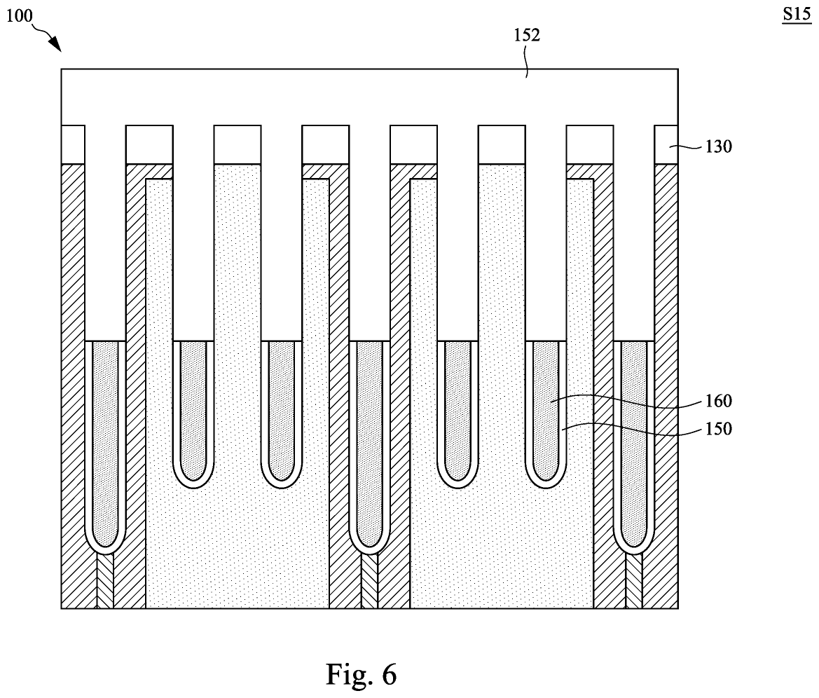

Reference is made to FIG. 6. As shown in step S15, a deposition process is performed to fill the trenches 140 (as shown in FIG. 4) with an oxide material 152. The oxide material 152 is in contact with the bottom conductive layers 160 and the lining layer 150. The remaining lining layer 150 above the bottom conductive layers 160 (if exist) is combined with the oxide material 152. In some embodiments, the oxide material 152 is seamless filled in the trenches 140, and the oxide material 152 is deposited on the top surface of the hard mask layer 130.

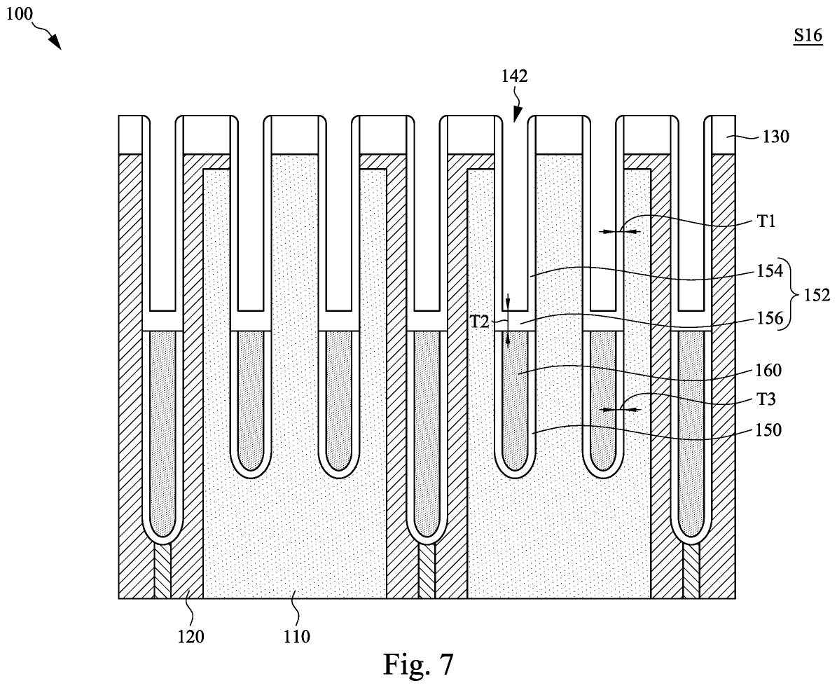

Reference is made to FIG. 7. As shown in step S16, a planarization process is performed to the excess portion above the hard mask layer 130 of the oxide material 152, and then an etching process is performed to remove portions of the oxide material 152 in the trenches 140 (as shown in FIG. 5). In some embodiments, the etching process to remove portions of the oxide material 152 in the trenches 140 is directional, and upper trenches 142 are defined above the bottom conductive layers 160 after the etching process. The upper trenches 142 are narrower than the trenches 140, and the upper trenches 142 have the same depths at the active regions 110 and the isolation region 120.

The oxide material 152 is remained in the upper trenches 142 after the etching process. The oxide material 152 has a first portion 154 on the sidewall of the upper trenches 142 and a second portion 156 on the bottom of the upper trenches 142. The oxide material 152 is directly in contact with the lining layer 150 and the bottom conductive layers 160. In some embodiments, the thickness T2 of the second portion 156 of the oxide material 152 is thicker than the thickness T1 of the first portion 154 of the oxide material 152. In some embodiments, the thickness T1 of the first portion 154 of the oxide material 152 is similar to the thickness T3 of the lining layer 150 that surrounds the bottom conductive layers 160.

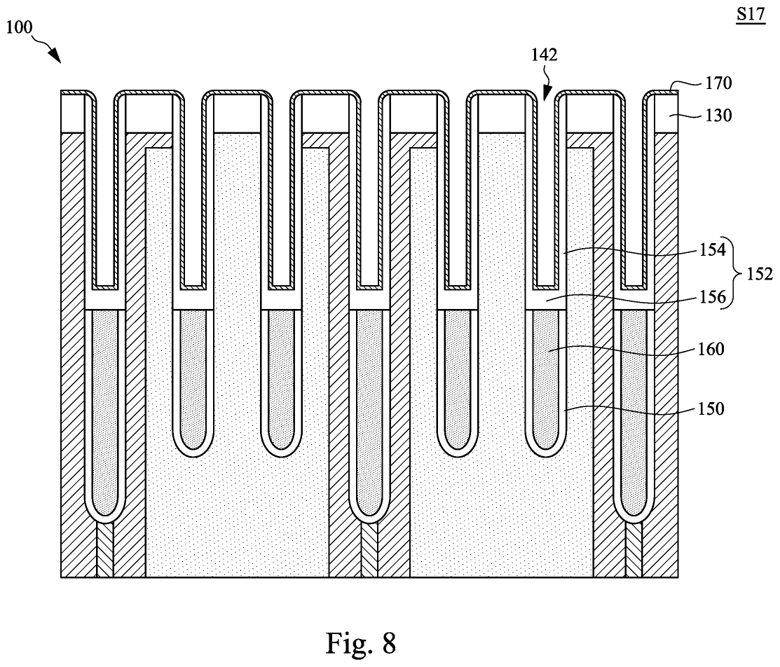

Reference is made to FIG. 8. As shown in step S17, a nitride layer 170 is formed on the hard mask layer 130, the upper trenches 142, and top surface of second portion 156 of the oxide material 152. In some embodiments, the nitride layer 170 is formed by an atomic layer deposition process such that the nitride layer 170 is conformally formed on the hard mask layer 130, the sidewalls of the upper trenches 142, and the top surface of the top surface of second portion 156 of the oxide material 152. In some embodiments, upper trenches 142 are not completely filled by the nitride layer 170.

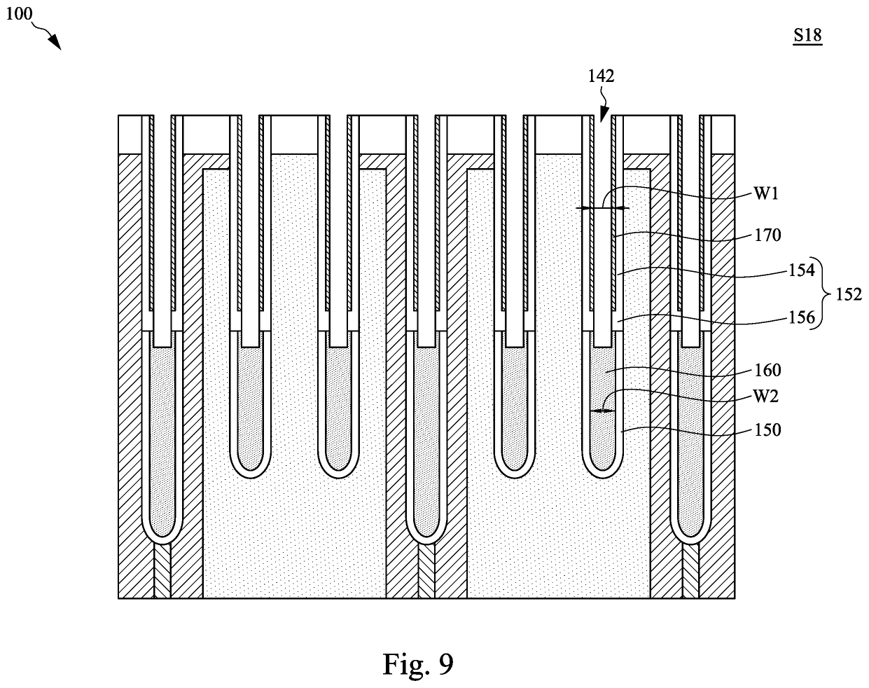

Reference is made to FIG. 9. As shown in step S18, a directional etching process is performed to remove lateral portions of the nitride layer 170, and the vertical portions of the nitride layer 170 are remained on sidewalls of the upper trenches 142. The directional etching process further remove portions of the second portion 156 of the oxide material 152 and portions of the bottom conductive layers 160.

Namely, the upper trenches 142 are deepened and are extended into the bottom conductive layers 160 after the directional etching process is performed. The sidewalls of the nitride layer 170, the second portion 156 of the oxide material 152, and the bottom conductive layers 160 exposed by the upper trenches 142 are substantially aligned after the directional etching process is performed.

The width W1 of each of the upper trenches 142 is less than the width W2 of each of the bottom conductive layers 160. The bottom of the each of the upper trenches 142 is surrounded by the each of the bottom conductive layers 160. That is, portions of the bottom conductive layers 160 are remained between the upper trenches 142 and the lining layer 150.

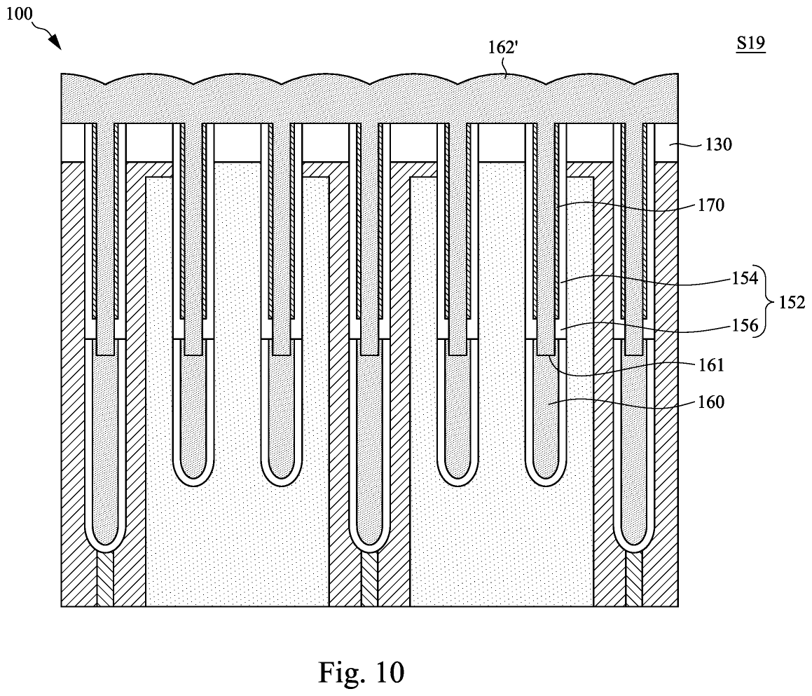

Reference is made to FIG. 10. As shown in step S19, an additional conductive material 162′ is deposited filling the upper trenches 142 (as shown in FIG. 9) and over the hard mask layer 130. The gap between the vertical portions of the nitride layer 170 is filled by the additional conductive material 162′, and the additional conductive material 162′ is connected to the bottom conductive layers 160. In some embodiments, the material of the additional conductive material 162′ can be the same as the material of the bottom conductive layers 160, such as titanium nitride or tungsten. In some embodiments, an interface 161 is present between the additional conductive material 162′ and the bottom conductive layers 160.

In some embodiments, the additional conductive material 162′ completely fills the upper trenches 142 and directly contacts the nitride layer 170, the second portion 156 of the oxide material 152, and the bottom conductive layers 160. The additional conductive material 162′ at the bottom of the upper trenches 142 is surrounded by the bottom conductive layers 160, respectively.

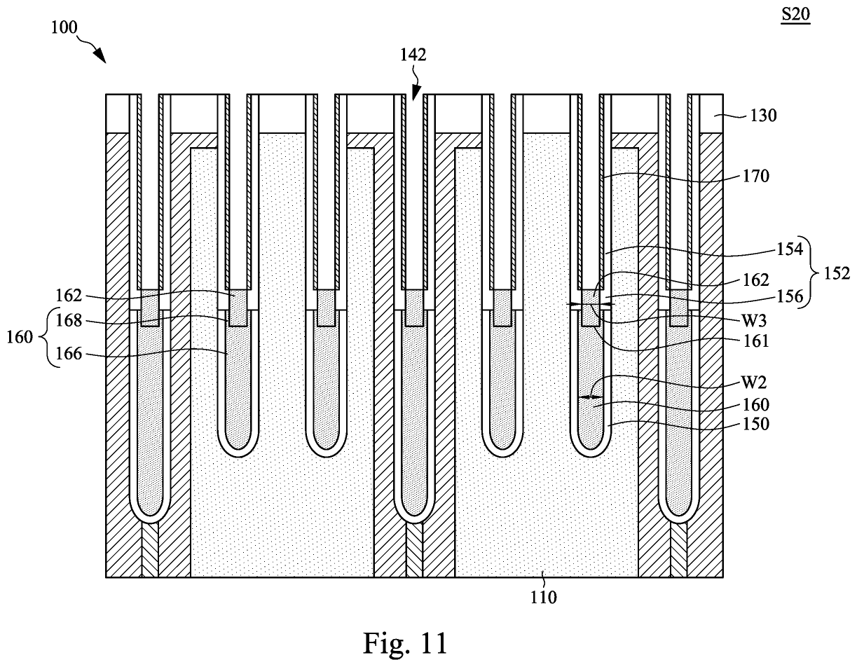

Reference is made to FIG. 11. As shown in step S20, an etch back process is performed to remove portions of the additional conductive material 162′ (as shown in FIG. 10) in the upper sections of the upper trenches 142 and portions of the additional conductive material 162′ over the hard mask layer 130, and portions of the additional conductive material 162′ at bottom sections of the upper trenches 142 are remained on the bottom conductive layers 160. As a result, portions of the additional conductive material 162′ can be regarded as top conductive layers 162 above the bottom conductive layers 160.

In some embodiments, the etch back process is performed to remove the portions of the additional conductive material 162′ between the nitride layer 170, and the portions of the additional conductive material 162′ between the second portion 156 of the oxide material 152 are remained. The width W3 of each of the top conductive layers 162 is less than the width W2 of each of the bottom conductive layers 160. The interface 161 is present between the top conductive layers 162 and the bottom conductive layers 160.

The upper section of the sidewall of each of the top conductive layers 162 is in contact with the second portion 156 of the oxide material 152, and the lower section of the sidewall of each of the top conductive layers 162 is in contact with each of the bottom conductive layers 160. The bottom surface of the each of the top conductive layers 162 is in contact with the top surface of each of the bottom conductive layers 160. Each of the bottom conductive layers 160 has a bottom portion 166 entirely below each of the top conductive layers 162 and a sidewall portion 168 encircling the bottom of each of the top conductive layers 162.

In some embodiments, the material of the top conductive layers 162 is the same as the material of the bottom conductive layers 160, thus the work function of the top conductive layers 162 is identical to the work function of the bottom conductive layers 160.

In some embodiments, the nitride layer 170 at top sections of the upper trenches 142 can be protect the active regions 110 during the etch back process, and thus the loss of the active regions 110 can be prevented.

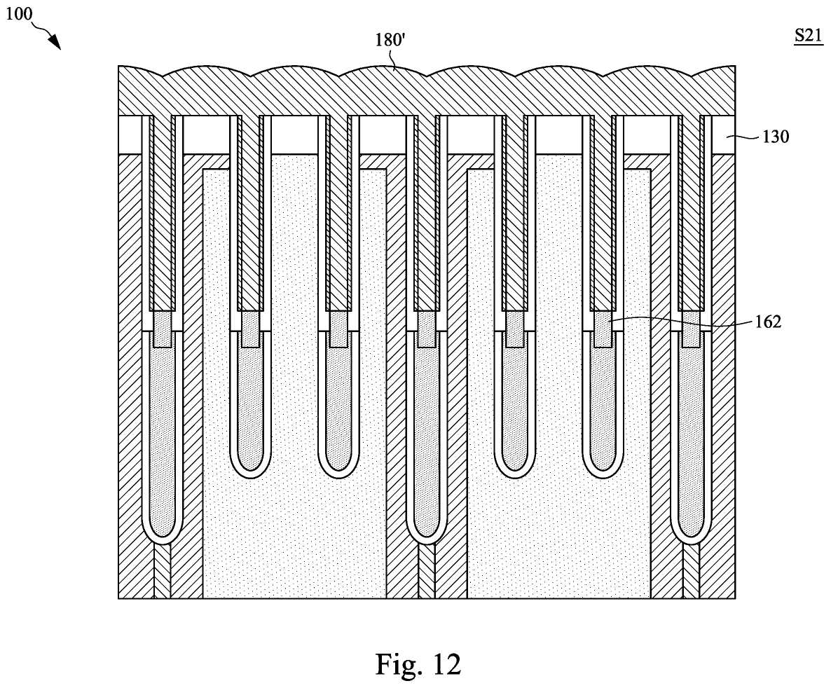

Reference is made to FIG. 12. As shown in step S21, a cap material 180′ is deposited filling the upper trenches 142 (as shown in FIG. 11) and above the hard mask layer 130. The cap material 180′ is deposited on the top conductive layers 162 and fills the upper trenches 142. The cap material 180′ for example can be a nitride such as silicon nitride.

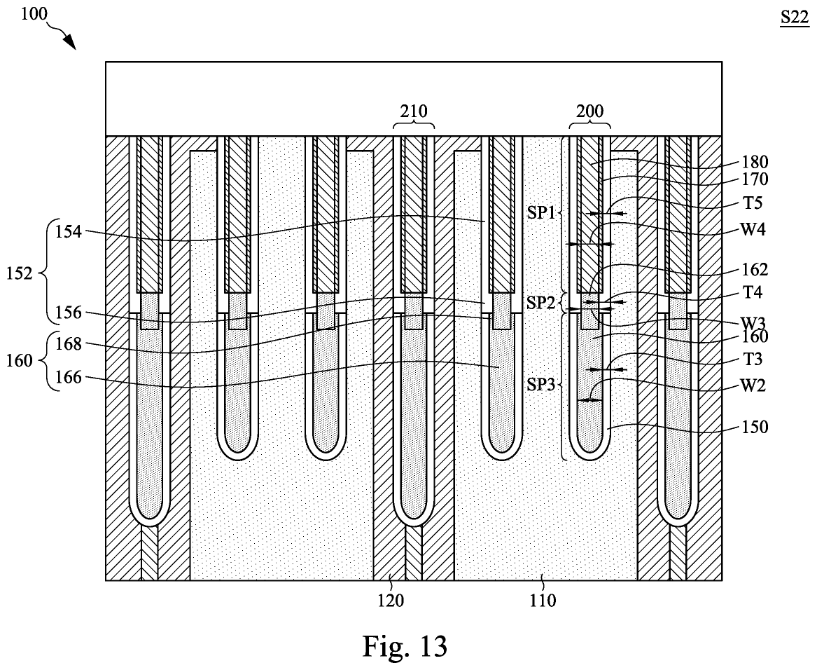

Reference is made to FIG. 13. As shown in step S22, a planarization process is performed to remove the hard mask layer 130 (as shown in FIG. 12) and portions of the cap material 180′ (as shown in FIG. 12) to expose the active regions 110 and the isolation region 120 again. The remaining cap material 180′ in the upper trenches 142 (as shown in FIG. 11) can be regarded as cap layers 180 above the top conductive layers 162. The width W4 of each of the cap layers 180 is equal to than the width W3 of each of the top conductive layers 162. The top surfaces of the active regions 110, the isolation region 120, the cap layers 180, the first portion 154 of the oxide material 152, and nitride layer 170 are coplanar after the planarization process is performed. Then a dielectric layer 190 is formed on the top surfaces of the active regions 110, the isolation region 120, and the cap layers 180.

Please refer to both FIG. 1 and FIG. 13. The semiconductor device 100 including the active regions 110, the isolation region 120, and the word lines WLs is provided. Each of the word lines WLs has a plurality of segments in the active regions 110, as the gate structures 200, and a plurality of segments in the isolation region 120, as the dummy gate structures 210. In some embodiments, the dummy gate structures 210 extend deeper than the gate structures 200.

Each of the gate structures 200 includes the bottom conductive layer 160, the top conductive layer 162, and the cap layer 180. The bottom conductive layer 160 is surrounded by the lining layer 150. The top conductive layer 162 is disposed on the bottom conductive layer 160, and the bottom of the top conductive layer 162 is embedded in the bottom conductive layer 160. The top conductive layer 162 is surrounded by the second portion 156 of the oxide material 152 and the sidewall portion 168 of the bottom conductive layer 160. The cap layer 180 is disposed on the top conductive layer 162 and is surrounded by the nitride layer 170 and the first portion 154 of the oxide material 152.

In some embodiments, the first portion 154 of the oxide material 152 and the nitride layer 170 together are regarded as a first spacer SP1 surrounding the cap layer 180, the second portion 156 of the oxide material 152 is regarded as a second spacer SP2 surrounding the top conductive layer 162, and the lining layer 150 is regarded as a third spacer SP3 surrounding the bottom conductive layer 160.

In some embodiments, the thickness T4 of the second spacer SP2 is thicker than the thickness T3 of the third spacer SP3, and the thickness T4 of the second spacer SP2 is equal to the thickness T5 of the first spacer SP1. Accordingly, the width W4 of the cap layer 180 is equal to the width W3 of the top conductive layer 162, and the width W2 of the bottom conductive layer 160 is wider than the width W3 of the top conductive layer 162.

In some embodiments, the top conductive layer 162 and the bottom conductive layer 160 are made of the same material such as titanium nitride or tungsten, and thus the word line WL has a single work function. In some embodiments, the lining layer 150 in the dummy gate structure 210 can be thicker than the lining layer 150 in the gate structure 200.

In each of the gate structure 200, the bottom conductive layer 160 and the top conductive layer 162 are made of the same conductive material thus the resistance (R) of the single work function gate structure 200 is relative lower than dual or multiple work function gate structure. The bottom conductive layer 160 is surrounded by the thinner third spacer SP3 which can increase the resistive current between the drain and the source (Ids). The top conductive layer 162 is surrounded by the thicker second spacer SP2 which is benefit to improve gate induced drain leakage (GIDL).

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A semiconductor device, comprising:
a substrate;
an active region in the substrate; and
a gate structure in the active region, the gate structure comprising a bottom conductive layer, a top conductive layer on the bottom conductive layer, and a cap layer on the top conductive layer, wherein a width of the top conductive layer is less than a width of the bottom conductive layer, a bottom of the top conductive layer is embedded in the bottom conductive layer, and a work function of the top conductive layer is identical to a work function of the bottom conductive layer.

2. The semiconductor device of claim 1, wherein the bottom conductive layer comprises a bottom portion entirely below the top conductive layer and a sidewall portion encircling the bottom of the top conductive layer.

3. The semiconductor device of claim 1, wherein a material of the bottom conductive layer and the top conductive layer comprises titanium nitride.

4. The semiconductor device of claim 1, wherein a material of the cap layer comprises silicon nitride.

5. The semiconductor device of claim 1, wherein an interface is present between the bottom conductive layer and the top conductive layer.

6. The semiconductor device of claim 1, further comprising:
a first spacer surrounding the cap layer; and
a third spacer surrounding the bottom conductive layer, wherein a thickness of the first spacer is thicker than a thickness of the third spacer.

7. The semiconductor device of claim 6, wherein the first spacer comprises a nitride layer in contact with the cap layer and a first portion of an oxide material between the nitride layer and the active region.

8. The semiconductor device of claim 7, further comprising:
a second spacer surrounding the top conductive layer, wherein a thickness of the second spacer is thicker than a thickness of the third spacer.

9. The semiconductor device of claim 8, wherein the second spacer comprises a second portion of the oxide material, and a thickness of the second portion of the oxide material is thicker than a thickness of the first portion of the oxide material.

10. The semiconductor device of claim 9, wherein a sidewall of the nitride layer is aligned with a sidewall of the second portion of the oxide material.

11. The semiconductor device of claim 1, further comprising:
an isolation region in the substrate; and
a dummy gate structure in the isolation region, wherein the dummy gate structure extends deeper than the gate structure in the substrate.

12. A method of forming a semiconductor device, the method comprising:
forming an active region in a substrate;
forming a trench in the active region;
depositing a lining layer in the trench;
depositing a conductive material to fill the trench;
etching back the conductive material and the lining layer to form a bottom conductive layer in the trench;
depositing an oxide material on the bottom conductive layer;
etching the oxide material to define an upper trench above the bottom conductive layer;
deepening the upper trench such that a portion of the bottom conductive layer is removed; and
forming a top conductive layer in the upper trench, after deepening the upper trench, wherein a width of the top conductive layer is less than a width of the bottom conductive layer, a bottom of the top conductive layer is embedded in the bottom conductive layer, and a work function of the top conductive layer is identical to a work function of the bottom conductive layer.

13. The method of claim 12, wherein the top conductive layer is directly in contact with the bottom conductive layer, and an interface is present between the top conductive layer and the bottom conductive layer.

14. The method of claim 12, wherein etching the oxide material comprises forming a first portion of the oxide material on a sidewall of the upper trench and a second portion of the oxide material on a bottom of the upper trench, and a thickness of the second portion is thicker than a thickness of the first portion.

15. The method of claim 14, further comprising:
depositing a nitride layer on the first portion and the second portion of the oxide material.

16. The method of claim 15, wherein deepening the upper trench comprises removing a portion of the nitride layer, a portion of the second portion of the oxide material, and the portion of the bottom conductive layer.

17. The method of claim 16, wherein sidewalls of the nitride layer, the second portion of the oxide material, and the bottom conductive layers exposed by the upper trench are aligned after deepening the upper trench.

18. The method of claim 16, wherein forming a top conductive layer comprises:
depositing additional conductive material to fill the upper trench; and
etching back the additional conductive material to remove a portion of the additional conductive material between the nitride layer.

19. The method of claim 12, further comprising:
depositing a cap material to fill the upper trench and above the active region; and
removing a portion of the cap material to form a cap layer on the top conductive layer.

20. The method of claim 19, wherein a width of the cap layer is equal to the width of the top conductive layer.
